(19) United States
(12) Patent Application Publication
(10) Pub. No.: US 2024/0097700 A1
(43) Pub. Date: Mar. 21, 2024

(54) SUCCESSIVE COMPARISON TYPE A/D CONVERTER

(71) Applicant: ROHM CO., LTD., Kyoto-shi (JP)

(72) Inventor: Koichi SAITO, Kyoto-shi (JP)

(21) Appl. No.: 18/466,539

(22) Filed: Sep. 13, 2023

(30) Foreign Application Priority Data
Sep. 16, 2022 (JP) 2022-148551

(51) Int. Cl. H03M 1/46

(52) U.S. Cl. CPC H03M 1/466

(57) ABSTRACT

The present disclosure provides a successive comparison type A/D converter. The successive comparison type A/D converter includes a D/A converter, configured to generate an analog output voltage according to a digital input; a comparator, configured to compare a voltage according to an analog input signal with an output voltage of the D/A converter; and a control circuit, configured to input the digital input to the D/A converter. The D/A converter includes: a capacitive D/A conversion circuit, including an output line connected to the comparator and a plurality of capacitors respectively connected to the output line; an isolation capacitor, connected to the output line; and a current source. The current source is configured to output a current signal to the output line through the isolation capacitor in synchronization with an input of the digital input to the D/A converter by the control circuit.

### CROSS REFERENCES TO RELATED APPLICATIONS

The present invention claims priority under 35 U.S.C. § 119 to Japanese Application, 2022-148551, filed on Sep. 16, 2022, the entire contents of which being incorporated herein by reference.

### TECHNICAL FIELD

The present disclosure relates to a successive comparison type analog-to-digital (A/D) converter.

### BACKGROUND

In the prior art, there are successive comparison type analog-to-digital converters (ADCs) (A/D converter) that convert analog signals into digital signals. In a successive comparison type ADC, a comparator successively compares a sampled analog input signal with a signal output from a digital-to-analog converter (DAC) (D/A converter), and a digital signal is output based on the comparison result.

### PRIOR ART DOCUMENT

### Patent Publication

[Patent document 1] Japan Patent Publication No. 2017-192099

### BRIEF DESCRIPTION OF THE DRAWINGS

FIG. 1 is a diagram of a configuration of a successive comparison type analog-to-digital converter (ADC) according to an embodiment of the present disclosure.

FIG. 2 is a circuit diagram of a configuration of a DAC of a reference example.

FIG. 3 is a timing diagram of an operation example of a successive comparison type ADC when the DAC of the reference example is used.

FIG. 4 is a circuit diagram of a DAC according to an embodiment of the present disclosure.

FIG. 5 is a circuit diagram of a configuration of a current source according to the embodiment.

FIG. 6 is a timing diagram for illustrating a current signal output by the current source according to the embodiment.

FIG. 7 is a diagram for illustrating effects of the successive comparison type ADC according to the embodiment.

FIG. 8 is a circuit diagram of a configuration of a DAC of a first variation example.

FIG. 9 is a circuit diagram of a configuration of a successive comparison type ADC of a second variation example.

### DETAILED DESCRIPTION OF THE EMBODIMENTS

### Summary

A summary of several exemplary embodiments of the present disclosure is provided below. The summary serves as the preamble of the detailed description to be given shortly and aims to provide fundamental understanding of the embodiments by describing several concepts of one or more embodiments in brief. It should be noted that the summary is not to be construed as limitations to the scope of the present disclosure. The summary is not a comprehensive summary of all conceivable embodiments, nor does it intend to specify important elements of all embodiments or to define the scope of a part of or all aspects. For the sake of better description, “one embodiment” sometimes refers to one embodiment (an implementation example or a variation example) or multiple embodiments (implementation examples or variation examples) described in the present disclosure.

According to an embodiment, a successive comparison type analog-to-digital (A/D) converter includes: a digital-to-analog (D/A) converter, configured to generate an analog output voltage according to a digital input; a comparator, configured to compare a voltage according to an analog input signal with an output voltage of the D/A converter; and a control circuit, configured to input the digital input to the D/A converter. The D/A converter includes: a capacitive D/A conversion circuit, including an output line connected to the comparator and a plurality of capacitors respectively connected to the output line; an isolation capacitor, connected to the output line; and a current source. The current source is configured to output a current signal to the output line through the isolation capacitor in synchronization with an input of the digital input to the D/A converter by the control circuit.

According to the configuration, a transient response signal generated due to a switching operation in the DAC can be eliminated via the current signal of the current source. Thus, signals can be converted with better precision.

In one embodiment, the isolation capacitor can also be a scaling capacitor of the capacitive D/A conversion circuit. With the configuration above, the resolution of the successive comparison type A/D converter can be increased without increasing the size of the capacitor.

In one embodiment, the successive comparison type A/D converter can also convert the analog input signal into an (M+N)-bit digital output signal, in which M and N are positive integers, the D/A converter further includes a resistive D/A conversion circuit connected to the capacitive D/A conversion circuit via the isolation capacitor, the resistive D/A conversion circuit is configured to output a signal corresponding to lower M bits to the output line, and the capacitive D/A conversion circuit is configured to output a signal corresponding to upper N bits to the output line. With the configuration above, the resolution of the successive comparison type A/D converter can be increased.

In one embodiment, the successive comparison type A/D converter can also convert the analog input signal into an (M+N)-bit digital output signal, in which M and N are positive integers, the D/A converter, when the capacitive D/A conversion circuit is a first capacitive D/A conversion circuit, further includes a second capacitive D/A conversion circuit connected to the first capacitive D/A conversion circuit via the isolation capacitor, the first capacitive D/A conversion circuit is configured to output a signal corresponding to upper M bits to the output line, and the second capacitive D/A conversion circuit is configured to output a signal corresponding to the lower N bits to the output line. With the configuration above, the resolution of the successive comparison type A/D converter can be increased.

In one embodiment, the current source can also be configured to adjust a waveform of the current signal. With the configuration above, a current signal having a desired waveform can be generated in a simple manner.

In one embodiment, the current source can include a source circuit configured to discharge current and a sink circuit configured to draw current. The source circuit can include a first transistor including a P-channel metal oxide semiconductor field effect transistor (MOSFET), and a plurality of second transistors including P-channel MOSFETs. The sink circuit can include a third transistor including an N-channel MOSFET, and a plurality of fourth transistors including N-channel MOSFETs. Each of the plurality of second transistors forms a current mirror circuit with the first transistor, and each of the plurality of fourth transistors forms a current mirror circuit with the third transistor. With the configuration above, a current signal having a desired waveform can be generated in a simple manner.

In one embodiment, the digital input can also include a control signal for controlling a voltage supplied to each of the plurality of capacitors, and the current source is configured to output the current signal having a waveform corresponding to the control signal. With the configuration above, a more appropriate current signal for eliminating a transient response signal can be generated.

### Embodiments

Details of preferred embodiments are provided with the accompanying drawings below. The same or equivalent constituent elements, parts and processes in the accompanying drawings are represented by the same denotations, and repeated description is omitted as appropriate. Moreover, the embodiments are illustrative and are not restrictive of the present disclosure. All features and combinations described in the embodiments are not necessarily intrinsic characteristics of the present disclosure.

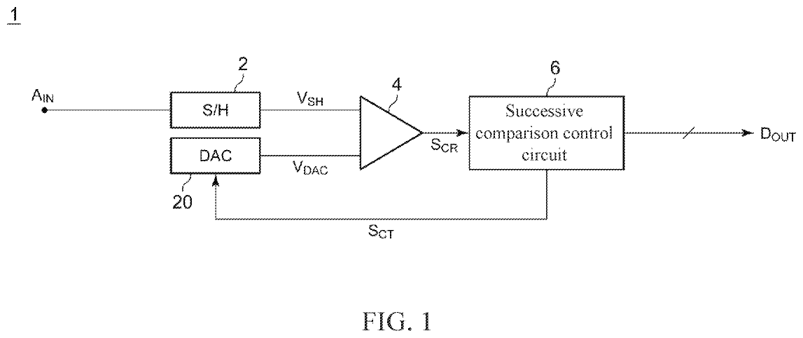

FIG. 1 shows a diagram of a configuration of a successive comparison type analog-to-digital converter (ADC) 1 according to an embodiment of the present disclosure. The successive comparison type ADC 1 of this embodiment converts an analog input signal A_{IN} into a 12-bit digital signal D_{OUT}. The successive comparison type ADC 1 includes a sample and hold circuit 2, a comparator 4, a successive comparison control circuit 6 and a digital-to-analog converter (DAC) 20.

The sample and hold circuit 2 samples and holds an input voltage. More specifically, the sample and hold circuit 2 samples a voltage based on the analog input signal A_{IN}, holds a sampled voltage V_{SH}, and outputs the voltage V_{SH} to the comparator 4.

The DAC 20 generates an analog output voltage according to a digital input S_{CT}. More specifically, the DAC 20 outputs an output voltage V_{DAC} according to the digital input S_{CT} input from the successive comparison control circuit 6 to the comparator 4.

The comparator 4 compares a voltage based on the analog input signal A_{IN} with the output voltage of the DAC 20. More specifically, the comparator 4 compares the voltage V_{SH} held by the sample and hold circuit 2 with the output voltage V_{DAC} output by the DAC 20, and outputs a comparison result signal S_{CR} to the successive comparison control circuit 6.

The successive comparison control circuit 6 outputs the digital input S_{CT} to the DAC 20. More specifically, the successive comparison control circuit 6 outputs the digital input S_{CT} to the DAC 20 based on the comparison result signal S_{CR} of the comparator 4 to control the operation of the DAC 20.

The DAC 20 outputs the output voltage V_{DAC} according to the digital input S_{CT} from the successive comparison control circuit 6, and the comparator 4 compares the voltage V_{SH} held by the sample and hold circuit 2 with the output voltage V_{DAC} and outputs the comparison result signal S_{CR} to the successive comparison control circuit 6. In the description below, the comparator 4 successively compares the voltage V_{SH} held by the sample and hold circuit 2 with the new output voltage V_{DAC} based on the comparison result signal S_{CR}. The successive comparison control circuit 6 outputs a digital output signal D_{OUT} based on a successive comparison result of the comparator 4. As such, the analog input signal A_{IN} is converted into a 12-bit digital output signal Dour.

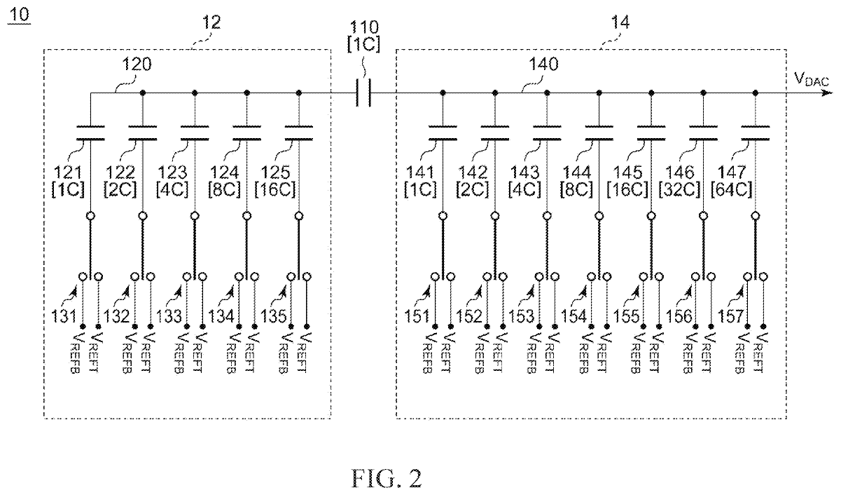

Herein, before details of the DAC 20 of this embodiment are given, a DAC 10 of a reference example substituting for the DAC 20 is first described. FIG. 2 shows a circuit diagram of a configuration of the DAC 10 of the reference example. The DAC 10 of the reference example includes a least significant bit (LSB) D/A conversion circuit, that is, an LSB circuit 12, a most significant bit (MSB) D/A conversion circuit, that is, an MSB circuit 14, and a scaling capacitor 110.

The LSB circuit 12 includes a common line 120, capacitors 121 to 125, and selectors 131 to 135. The capacitors 121 to 125 correspond to 5 lower bits. Capacitance values of the capacitors 121 to 125 are set with “C” as a reference capacitance value (in the description below, the capacitance values are respectively [1C], [2C], [4C], [8C] and [16C] when the reference capacitance value is similarly set to [C]. That is to say, each of the capacitors 121 to 125 has a capacitance value weighted by a specified ratio (=2^{x}C, where x is an integer between 0 and 4)).

One end of each of the capacitors 121 to 125 is connected to the common line 120. The other end of each of the capacitors 121 to 125 is connected to one of the selectors 131 to 135. The selectors 131 to 135 are configured to supply an upper reference voltage V_{REFT} (first reference voltage) or a lower reference voltage V_{REFB} (second reference voltage) to the other end of each of the capacitors 121 to 125 based on the digital input S_{CT} from the successive comparison control circuit 6. The reference voltage can be common with a power supply or be common with the ground. Moreover, in the description below, when the upper reference voltage V_{REFT} and the lower reference voltage V_{REFB} are not differentiated, they may be referred to as “reference voltage V_{REF}” for short.

The MSB circuit 14 includes an output line 140, capacitors 141 to 147, and selectors 151 to 157. The capacitors 141 to 147 correspond to 7 upper bits. The capacitance values of the capacitors 141 to 147 are respectively [1C], [2C], [4C], [8C], [16C], [32C] and [64C]. That is to say, each of the capacitors 141 to 147 has a capacitance value weighted by a specified ratio (=2^{y}C, where y is an integer between 0 and 6)).

One end of each of the capacitors 141 to 147 is connected to the output line 140. The other end of each of the capacitors 141 to 147 is connected to one of the selectors 151 to 157. The selectors 151 to 157 are configured to supply the upper reference voltage V_{REFT} or the lower reference voltage V_{REFB} to the other end of each of the capacitors 141 to 147 based on the digital input S_{CT} from the successive comparison control circuit 6.

The scaling capacitor 110 is between the LSB circuit 12 and the MSB circuit 14, and is connected in series between the LSB circuit 12 and the MSB circuit 14. More specifically, one end of the scaling capacitor 110 is connected to the common line 120 of the LSB circuit 12, and the other end of the scaling capacitor 110 is connected to the output line 140 of the MSB circuit 14. By disposing the scaling capacitor 110 at the DAC 10, the resolution of the successive comparison type ADC 1 can be increased without increasing the size of the capacitor of the MSB circuit 14. A capacitance value of the scaling capacitor 110 is [1C].

The selectors 131 to 135 and 151 to 157 are controlled by the digital input S_{CR} of the successive comparison control circuit 6. For example, for MSB decisions, the successive comparison control circuit 6 can control the selectors 131 to 135 and 151 to 157 by means of supplying the reference voltage V_{REFT} to the other end of the capacitor 147 corresponding to the MSB and supplying the reference voltage V_{REFB} to the other end of each of the remaining capacitors 121 to 125 and 141 to 146.

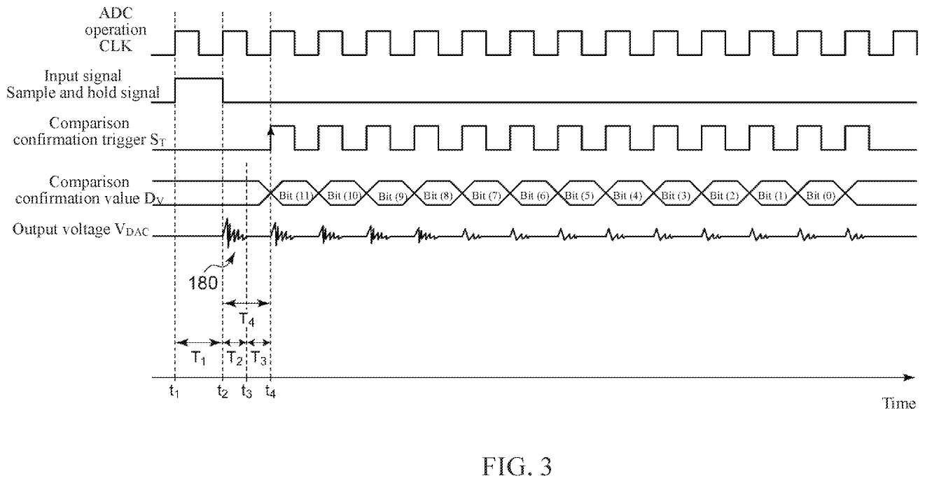

FIG. 3 shows a timing diagram of an operation example of a successive comparison type ADC when the DAC 10 of the reference example is used. In FIG. 3, an ADC operation signal CLK, an input signal sample and hold signal (also referred to as “hold signal” below), a comparison confirmation trigger S_{T}, a comparison confirmation value D_{V} and an output voltage V_{DAC} are depicted sequentially from the top.

In a sample period T₁ (timings t₁ to t₂), the hold signal is high, and the comparator 4 stops the successive comparison operation. At a timing t₂, if the hold signal lowers, the comparator 4 performs the successive comparison operation. For example, at a timing t₄, the ADC operation signal CLK rises, and the state of the selector of the DAC 10 switches to a state for determination of the MSB (bit 11).

While the ADC operation signal CLK rises, the comparison confirmation trigger S_{T} rises, and the comparator 4 performs a comparison operation. Then, switching between the high and low of the ADC operation signal CLK and the comparison confirmation trigger S_{T} sequentially takes place to perform the successive comparison operation of each bit. In the example in FIG. 3, the comparison operation is performed on 12 bits from bit 11 corresponding to the MSB to bit 0 corresponding to the LSB.

A signal of transient response (also referred to as “transient response signal” below) is generated when a state of the selector is switched. A path from a voltage source (not shown) of the reference voltage V_{REF} to the DAC 10 includes structures of, for example, an integrated circuit (IC) routing, a bonding wire, a lead frame, and a printed circuit board (PCB). With the configuration above, the transient response signal is carried in the reference voltage V_{REF} when the state the selector is switched. More particularly, a waveform of the transient response signal is affected by such as resonance of inductance components of the bonding wire.

The upper a bit is, when it is switched to a bit as a determination target (that is, the state of the selector is switched), the larger transient response signal is carried in the reference voltage V_{REF}. In the example in FIG. 3, when the state of the selector is switched at the timing t2, in a period T₂ between the timings t₂ and t₃, a transient response signal 180 is carried in the reference voltage V_{REF}. If the conversion speed of the DAC 10 is increased and a period T₄ of the ADC operation signal CLK and the comparison confirmation trigger S_{T} is shortened, a period T₃ in which the transient response signal 180 converges to the next switching is shortened. Thus, if the conversion speed of the DAC 10 is too fast, the comparison operation for a next bit may begin before the convergence of the transient response signal 180, hence affecting the comparison operation for the next bit.

In order to inhibit the transient response, a method of duplicating a bonding wire (WB) is carried out to reduce impedance does achieve a difference to a certain extent, with however the improvement being quite limited. There is another method of inserting a buffer into the reference voltage V_{REF} in order to fundamentally cut off impedance and performing driving near the DAC circuit 10 to improve the transient response. However, with the implementation of high precision and high speed of the DAC circuit 10, high accuracy and high speed are also needed in the performance of a buffer. However, power consumption caused by high speed yields a quite contrary result, and an offset of a buffer in terms of precision is also limited.

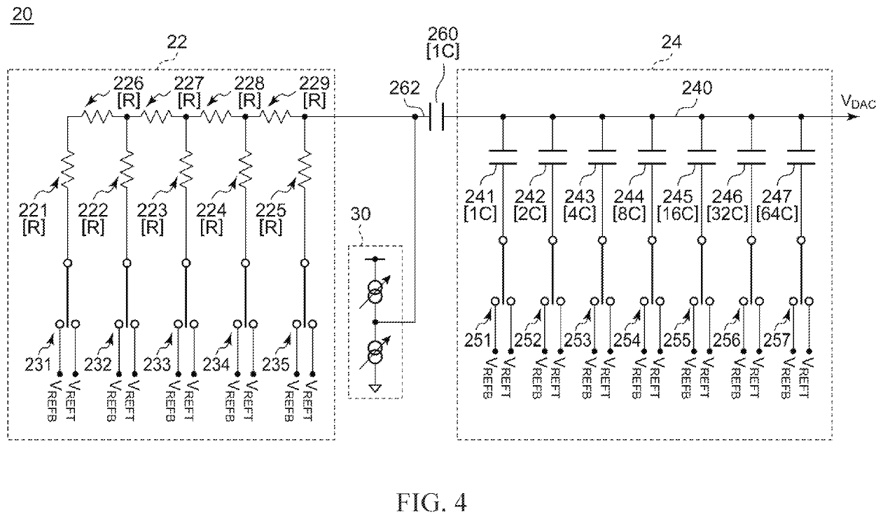

FIG. 4 shows a diagram of a successive comparison type DAC 20 according to an embodiment of the present disclosure. The DAC 20 of this embodiment includes an LSB circuit 22, an MSB circuit 24, a scaling capacitor 260 (isolation capacitor) and a current source 30.

The LSB circuit 22 of this embodiment is a step resistive D/A conversion circuit having a 5-bit resolution. The LSB circuit 22 includes resistors 221 to 229 and selectors 231 to 235. Resistance values of the resistors 221 to 229 are all [R]. The resistors 221 to 225 correspond to lower 5 bits among 12 bits. In the description of this embodiment, the LSB circuit 22 outputs signals corresponding to the 5 bits to an output line 240; however, the LSB circuit 22 can also be configured to output M-bit signals (where M is a positive integer) as desired to the output line 240.

The resistors 226 to 229 are sequentially connected in series. One end of the resistor 221 is connected to one end of the resistor 226, one end of the resistor 222 is connected between the other end of the resistor 226 and one end of the resistor 227, one end of the resistor 223 is connected between the other end of the resistor 227 and one end of the resistor 228, one end of the resistor 224 is connected between the other end of the resistor 228 and one end of the resistor 229, and one end of the resistor 225 is connected to the other end of the resistor 229.

The other end of each of the resistors 221 to 225 is connected to one of the selectors 231 to 235. The selectors 231 to 235 are configured to supply the upper reference voltage V_{REFT} or the lower reference voltage V_{REFB} to the other end of each of the resistors 221 to 225 based on the digital input S_{CT} from the successive comparison control circuit 6.

The MSB circuit 24 of this embodiment is a capacitive D/A conversion circuit having a 7-bit resolution. The MSB circuit 24 includes the output line 240 connected to the comparator 4, capacitors 241 to 247 individually connected to the output line 240, and selectors 251 to 257. The capacitors 241 to 247 correspond to 7 upper bits among 12 bits. In the description of this embodiment, the MSB circuit 24 outputs signals corresponding to the 7 bits to the output line 240; however, the MSB circuit 24 can also be configured to output N-bit signals (where N is a positive integer) as desired to the output line 240.

One end of each of the capacitors 241 to 247 is connected to the output line 240. The other end of each of the capacitors 241 to 247 is connected to one of the selectors 251 to 257. The selectors 251 to 257 are configured to supply the upper reference voltage V_{REFT} or the lower reference voltage V_{REFB} to the other end of each of the capacitors 241 to 247 based on the digital input S_{CT} from the successive comparison control circuit 6.

In this embodiment, the scaling capacitor 260 functions as a scaling capacitor that is configured as a capacitive D/A conversion circuit of the MSB circuit 24. The scaling capacitor 260 is between the LSB circuit 22 and the MSB circuit 24 and is connected in series between the LSB circuit 22 and the MSB circuit 24. More specifically, one end of the scaling capacitor 260 is connected to the other end of the resistor 229 and one end of the resistor 225 of the LSB circuit 22, and the other end of the scaling capacitor 260 is connected to the output line 240 of the MSB circuit 24.

The digital input Sc R includes a control signal for controlling on and off of the selectors 231 to 235 and 251 to 257 of the DAC 20. Based on the control signal, on and off of the selectors 231 to 235 and 251 to 257 are controlled, and a reference voltage supplied to the resistors 221 to 225 and the capacitors 241 to 247 is controlled.

The current source 30 is connected to a path 262 connecting the scaling capacitor 260 and the LSB circuit 22. The current source 30 outputs a current signal to the output line 240 through the scaling capacitor 260 in synchronization with an input of the digital input to the DAC 20 by the successive comparison control circuit 6. In this embodiment, the current source 30 is configured to output a current signal to the scaling capacitor 260 through a switch 360 according to the control signal input by the successive comparison control circuit 6. With the output current signal, the transient response signal generated in the reference voltage V_{REF} can be eliminated.

The current source 30 can also output a current signal having a waveform corresponding to a control signal. Accordingly, the current source 30 can output a current signal appropriate for further eliminating the transient response signal.

For example, according to the digital input S_{CT} of the successive comparison control circuit 6, the capacitor 247 corresponding to the MSB is connected to the reference voltage V_{REFT}, and the capacitor 246 corresponding to a bit less significant than the MSB is connected to the reference voltage V_{REFB}. Next, according to the new digital input S_{CT} based on the comparison result of the comparator 4, the selectors 256 and 257 are switched by connecting the capacitor 247 to the reference voltage V_{REFB} and connecting the capacitor 246 to the reference voltage V_{REFT}.

At this point in time, according to switching of the supplied reference voltage, since the capacitor corresponding to a more significant bit has a larger capacitance value, a transient response signal having a greater amplitude and longer duration is generated. Thus, as described above, when the selectors 256 and 257 are switched, it is switched to supply reference voltages of the capacitors 246 and 247 corresponding to upper bits including the MSB to generate the transient response signal having a greater amplitude and longer duration. On the other hand, when it is switched to supply the reference voltage of the capacitor 241 corresponding to the LSB in the MSB circuit 24, a transient response signal having a smaller amplitude and shorter duration is generated.

As such, the waveform of the transient response signal generated changes according to switching of the reference voltage supplied with. Thus, by controlling a change in the control signal according to switching of the reference voltage and hence a change in the waveform of the current signal, the current source 30 is capable of outputting a current signal that better satisfies the transient response signal.

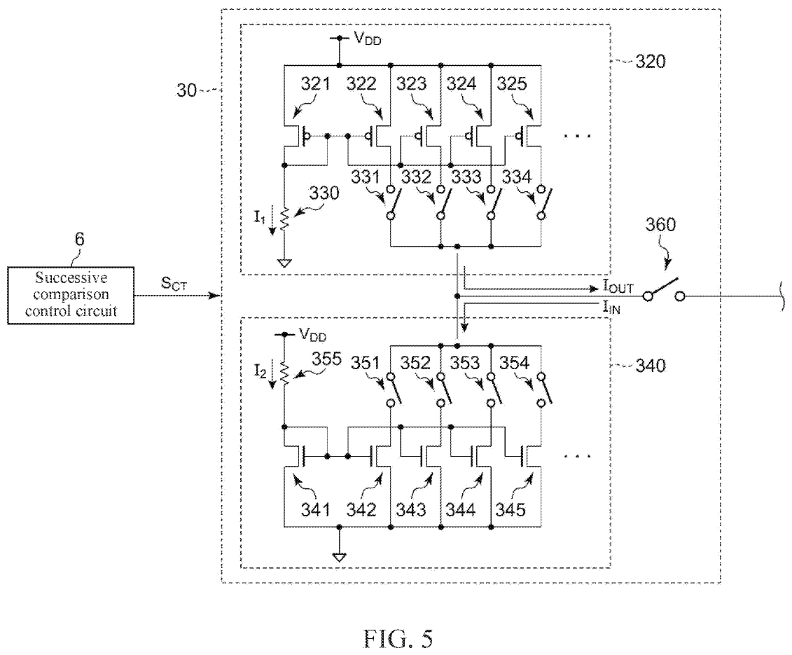

FIG. 5 shows a circuit diagram of a configuration of a current source 30 according to the embodiment. The current source 30 includes a source circuit 320 and a sink circuit 340. According to operations of the source circuit 320 and the sink circuit 340, a current I_{OUT} is discharged from the current source 30 to the scaling capacitor 260, or a current I_{IN} is drawn from the scaling capacitor 260 to the current source 30.

The source circuit 320 includes transistors 321 to 325, switches 331 to 334 and a resistor 330. Each of the transistors 321 to 325 includes a P-channel metal oxide semiconductor field effect transistor (MOSFET). Each of the transistors 322 to 325 (second transistor) forms a current mirror circuit with the transistor 321 (first transistor).

A source of each of the transistors 321 to 325 is supplied with a power supply voltage Vdd. A gate and a drain of the transistor 321 and a gate of each of the transistors 322 to 325 are commonly connected and are connected to one end of the resistor 330. Drains of the transistors 322 to 325 are connected to the switches 331 to 334. The other end of the resistor 330 is connected to the ground.

A current corresponding to a resistance value of the resistor 330 flows in the resistor 330. When at least any one of the switches 331 to 334 is turned on, a current equivalent to a current I₁ flowing in the resistor 330 flows in each of the turned-on switch. The currents flowing in the switches 331 to 334 flow from the source circuit 320 to the scaling capacitor 260 through the switch 360. Thus, by controlling the switches 331 to 334, the source circuit 320 can discharge a current that is X*I₁ (where X is a positive integer). The current discharged from the source circuit 320, as a current signal, is transmitted to the output line 240 through the scaling capacitor 260.

The source circuit 320 includes transistors 341 to 345, switches 351 to 354 and a resistor 355. Each of the transistors 341 to 345 includes an N-channel MOSFET. Each of the transistors 342 to 345 (fourth transistor) forms a current mirror circuit with the transistor 341 (third transistor).

Sources of the transistors 341 to 345 are commonly connected and are connected to the ground. A gate and a drain of the transistor 341 and a gate of each of the transistors 342 to 345 are connected to one end of the resistor 355. Drains of the transistors 342 to 345 are connected to the switches 351 to 354. The other end of the resistor 355 is connected to a power supply voltage VDD.

A current corresponding to a resistance value of the resistor 355 connected to a drain of the transistor 341 flows in the resistor 355. When at least any one of the switches 351 to 354 is turned on, a current equivalent to a current flowing in the resistor 355 flows in each of the turned-on switch. The currents flowing in the switches 351 to 354 are drawn from the scaling capacitor 260 through the switch 360 by the sink circuit 340. Thus, by controlling the switches 351 to 354, the sink circuit 340 can draw a current that is Y*I₁ (where Y is a positive integer). According to the current drawn to the sink circuit 340, a current signal is transmitted to the output line 240 via the scaling capacitor 260.

As described above, the current source 30 according to this embodiment is capable of discharging a current of a desired magnitude to the scaling capacitor 110 or drawing a current of a desired magnitude from the scaling capacitor 110 through operations of the source circuit 320 and the sink circuit 340. As a result, the current source 30 is capable of transmitting the current signal of a desired magnitude to the output line 140 through the scaling capacitor 110.

Moreover, the waveform of the current signal can be adjusted by controlling turning on and off of the switches 331 to 334 and 351 to 354. In addition, a timing, and a period at/in which the current source 30 outputs the current signal can be adjusted by controlling timings of turning on and off the switches 331 to 334 and 351 to 354 and by controlling periods of maintaining said state.

Moreover, in this embodiment, although the source circuit 320 and the sink circuit 340 using different switches 360 to control the output of the current signal of the current source 30 is given as an example, the present disclosure is not limited to such example. For example, the switch 360 may be omitted, and the output of the current signal is controlled only by the switches 331 to 334 of the source circuit 320 and the switches 351 to 354 of the sink circuit 340.

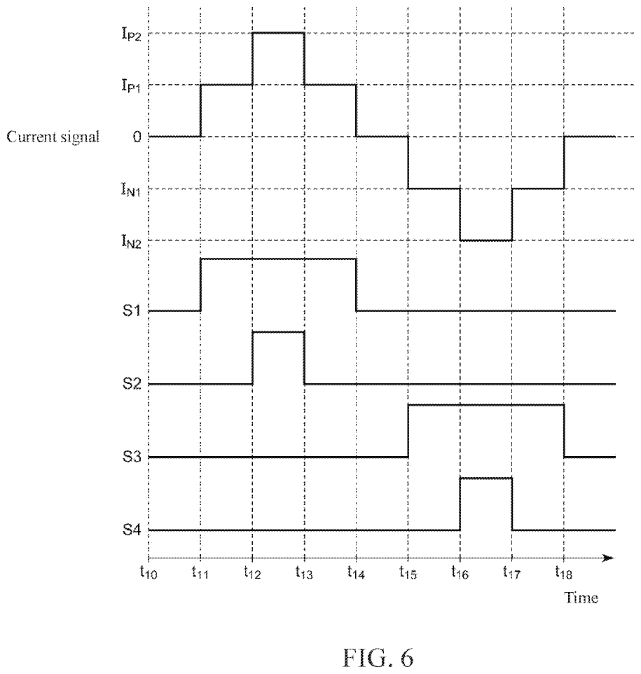

FIG. 6 shows a timing diagram for illustrating a current signal output by the current source 30 according to the embodiment. In FIG. 6, a current signal, a first switch signal S1, a second switch signal S2, a third switch signal S3 and a fourth switch signal S4 are sequentially depicted from the top. The first switch signal S1, the second switch signal S2, the third switch signal S3 and the fourth switch signal S4 are respectively for controlling turning on and off of the switches 331, 332, 351 and 342. Herein, the switches 333, 334, 353 and 354 are turned off in the description below.

At a timing t₁₀, the first switch signal S1, the second switch signal S2, the third switch signal S3 and the fourth switch signal S4 are low, and the switches 331, 332, 351 and 342 are turned off. Thus, the current source 30 does not generate any current signal.

At a timing t₁₁, the switch 331 is turned on when the first switch signal S1 becomes high, and a current signal I_{P1} (>0) is output from the current source 30. At a timing t₁₂, the switch 332 is turned on when the second switch signal S2 becomes high, and the current signal I_{P1} output from the current source 30 becomes I_{P2} (>I_{P1}). Next, at a timing t₁₃, the switch 332 is turned off when the second switch signal S2 becomes low, and the current signal I_{P2} output from the current source 30 becomes I_{P1}. At a timing t₁₄, the switch 331 is turned off when the first switch signal S1 becomes low, and the current source 30 does not output any current signal.

At a timing t₁₅, the switch 351 is turned on when the third switch signal S3 becomes high, and a current signal I_{N1} (<0) is output from the current source 30. At a timing t₁₆, the switch 352 is turned on when the fourth switch signal S4 becomes high, and the current signal I_{P3} output from the current source 30 becomes I_{P4} (<I_{P3}). Next, at a timing t₁₇, the switch 352 is turned off when the fourth switch signal S4 becomes low, and the current signal I_{P4} output from the current source 30 becomes I_{P3}. Moreover, at a timing t₁₈, the switch 351 is turned off when the third switch signal S3 becomes low, and the current source 30 does not output any current signal. As described above, the current source 30 according to this embodiment can generate a current signal having a waveform corresponding to the control of turning on and off of the switches.

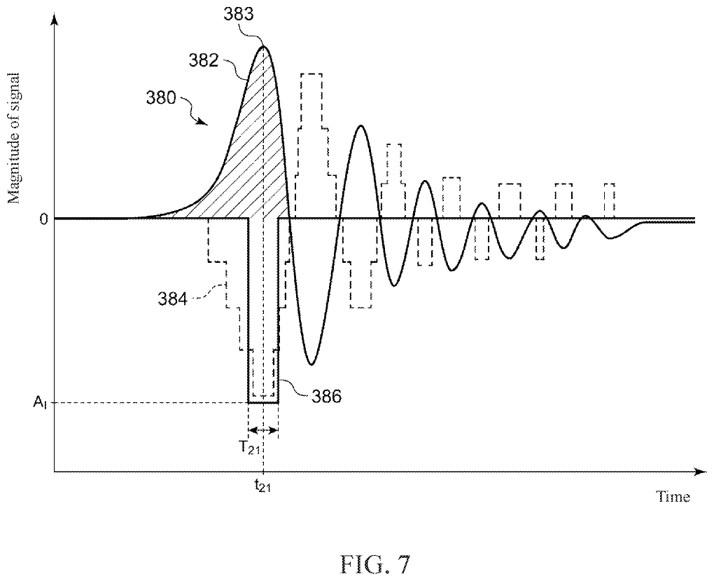

FIG. 7 is a diagram for illustrating effects of the successive comparison type ADC according to the embodiment. Herein, two types of current signals (first current signal and second current signal) are described with reference to FIG. 7. FIG. 7 shows a waveform (in a solid line) of a transient response signal 380 generated in the output line 240, and a waveform (in a dotted line) of a first current signal 384 and a waveform (in a solid line) of a second current signal 386 transmitted by the current source 30. In FIG. 7, the vertical axis represents the magnitude of signals and the horizontal axis represents time.

First of all, an example of the current source 30 outputting the first current signal 384 is described. The waveform of the first current signal 384 of the current source 30 is adjusted to be the same as the waveform of the transient response signal 380, and the first current signal 384 is transmitted to the output line 240 at a timing at which the transient response signal 380 is generated in the output line 240, hence eliminating the transient response signal 380 by the first current signal 384. More specifically, at switching timings of the selectors 231 to 235 and 251 to 257, the transient response signal 380 can be eliminated by the first current signal 384 output by the current source 30. Hence, the transient response signal 380 can be inhibited from affecting the comparison operation of the comparator 4, allowing the comparator 4 to perform the comparison operation with better precision, thereby more accurately converting the analog input signal A_{IN} into the digital output signal D_{OUT}.

Next, an example of the current source 30 outputting the second current signal 386 in substitution for the first current signal 384 to the output line 240 is described. The second current signal 386 is generated as a rectangular pulse signal to eliminate at least a part of a first peak 382 of the transient response signal 380. More specifically, the second current signal 386 has a magnitude A₁ in a positive/negative polarity opposite to the peak 382 in a period T₂₁ in which the peak 382 achieves a peak value 383 at a timing t₂₁, and the magnitude of the second current signal 386 may be 0 in other times.

When the current source 30 outputs the second current signal 386, high-speed control such as that when the first current signal 384 is output is not needed. Thus, the current source 30 can eliminate at least a part of the transient response signal 380 by simpler control. Moreover, because the first peak 382 is greater than the remaining waveform of the transient response signal 380, at least a part of the peak 382 can be eliminated to more effectively eliminate the transient response signal 380.

As such, by transmitting a current signal 362 to the output line 240 through the scaling capacitor 260 (isolation capacitor), the successive comparison type ADC according to this embodiment is capable of inhibiting the transient response signal 380 from affecting the comparison operation of the comparator 4. In addition, the scaling capacitor 260 insulates the MSB circuit 24 and the current source 30 from each other. Thus, when the current source 30 operates, charge accumulated in the capacitors 241 to 247 of the MSB circuit 24 that is affected by the operations of the current source 30 is inhibited. As a result, the comparator 4 is allowed to perform the comparison operation with better precision.

Moreover, when a state of the selector corresponding to the capacitor corresponding to an upper bit is switched, the transient response signal is larger. Thus, the current source 30 can adjust the current signal according to the capacitance value of the switched capacitor supplying the reference voltage. More specifically, in the current source 30, the current signal is increased as the bit corresponding to the switched capacitor gets more significant. Thus, the magnitude of the current signal output by the current source 30 can easily meet the magnitude of the transient response signal. As a result, the transient response signal can be eliminated with better precision.

As described above, if the conversion speed of the successive comparison type ADC is accelerated, the transient response signal is more likely to affect the comparison operation of the comparator. According to this embodiment, since the transient response signal can be inhibited, the influence of the transient response signal upon the comparison operation can be inhibited, hence increasing the conversion speed of the successive comparison type ADC.

### First Variation Example

In the first variation example, a DAC of the successive comparison type ADC is different from that of the embodiment. The remaining parts of the configuration details and operations in the first variation example are the same as those of the embodiment above. Moreover, the structures of the embodiment and the first variation example may also be combined as desired.

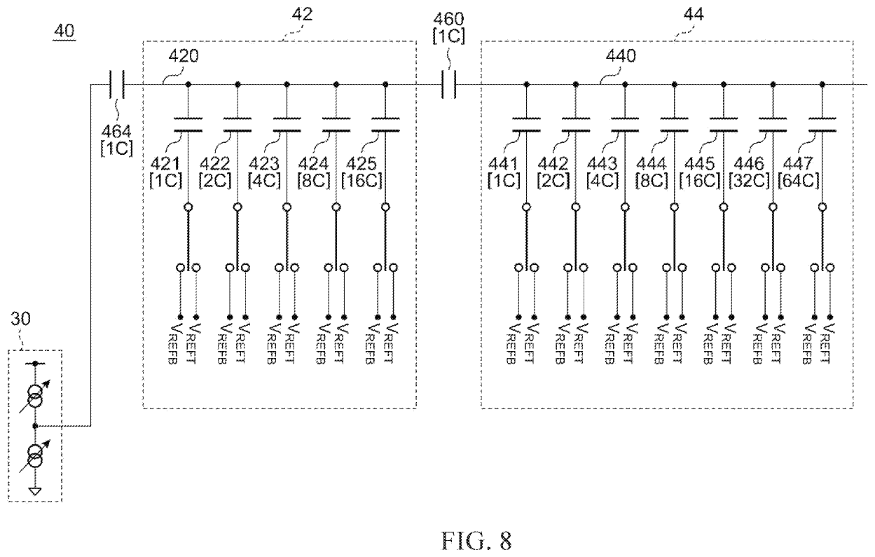

FIG. 8 shows a circuit diagram of a configuration of a DAC 40 of a first variation example. The DAC 40 of the first variation example includes an LSB circuit 42, an MSB circuit 44, a scaling capacitor 460, an isolation capacitor 464 and a current source 30.

The LSB circuit 42, the MSB circuit 44 and the scaling capacitor 460 have configuration details substantially the same as those of the LSB circuit 12, the MSB circuit 14 and the scaling capacitor 110 illustrated in FIG. 2, and such repeated details are omitted herein.

In the first variation example, the current source 30 is connected to a common line 420 of the LSB circuit 42 via the isolation capacitor 464. The current source 30 transmits a current signal to an output line 440 of the MSB circuit 44 through the isolation capacitor 464 and the scaling capacitor 460. Hence, the transient response signal generated in the output line 440 can be eliminated by the current signal to enhance the precision of the comparison operation of the comparator 4, thereby more accurately converting the analog input signal A_{IN} into the digital output signal Dour.

### Second Variation Example

A successive comparison type ADC 50 of the second embodiment is in the differential form and converts analog input signals V_{IN+} and V_{IN-} into a 12-bit digital output signal D_{OUTM}. Moreover, the structures of the embodiment and the first and second variation examples may also be combined as desired.

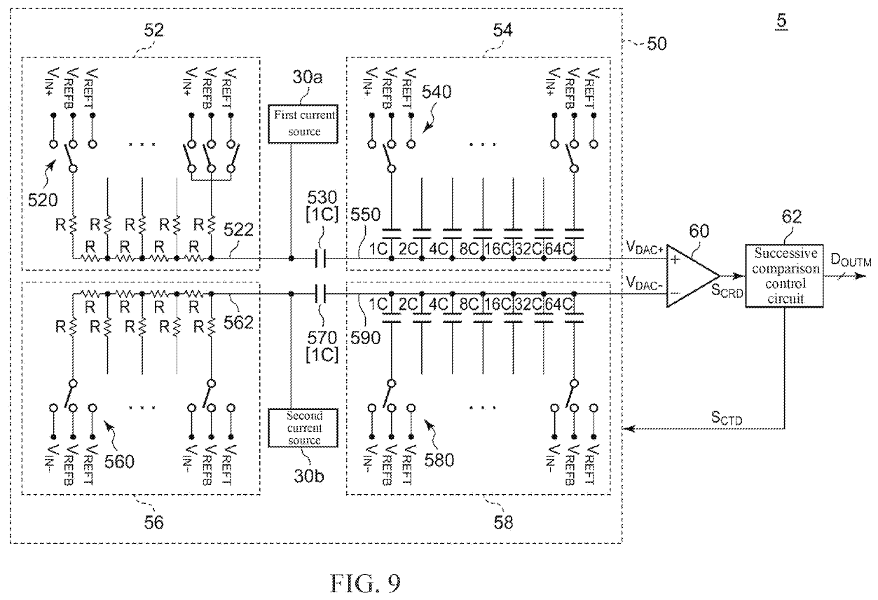

FIG. 9 shows a diagram of a configuration of a successive comparison type ADC 50 of the second variation example. The successive comparison type ADC 50 of the second variation example primarily includes a DAC 50, a comparator 60 and a successive comparison control circuit 62.

The comparator 60 compares an output voltage V_{DAC+} output from a positive side of the DAC 50 and an output voltage V_{DAC-} output from a negative side of the DAC 50, and outputs a comparison result signal S_{CRD} to the successive comparison control circuit 62. The successive comparison control circuit 62 inputs a digital input S_{CTD} to the DAC 50 based on the comparison result signal S_{CRD}. Then, the comparator 60 successively compares the output voltage V_{DAC+} of the positive side with the output voltage V_{DAC-} of the negative side, and the successive comparison control circuit 62 outputs a digital output signal D_{OUTM} corresponding to the successive comparison result.

The DAC 50 of the second variation example includes a first current source 30a, a second current source 30b, a first LSB circuit 52, a first MSB circuit 54, a second LSB circuit 56 and a second MSB circuit 58.

The LSB circuit 52 is a step resistive D/A conversion circuit having a 5-bit resolution. The first LSB circuit 52 includes nine resistors having a resistance value [R]. The nine resistors are connected similarly as the nine resistors 221 to 229 in FIG. 4. Among the resistors, each of the five resistors corresponding to lower five bits is connected to a selector 520. The selector 520 is configured to supply the analog input signal V_{IN+} of the positive side, the upper reference voltage V_{REFT} or the lower reference voltage V_{REFB} to the resistor based on a digital input from the successive comparison control circuit 62.

The first MSB circuit 54 is a capacitive D/A conversion circuit having a 7-bit resolution. The first MSB circuit 54 includes seven capacitors corresponding to seven MSB bits, and the capacitors respectively have capacitance values [1C], [2C], [4C], [8C], [16C], [32C] and [64C]. One end of each of the capacitors is connected to an output line 550, and the other end of each of the capacitors is connected to the selector 540. The selector 540 is configured to supply the analog input signal V_{IN+} of the positive side, the upper reference voltage V_{REFT} or the lower reference voltage V_{REFB} to the capacitor based on a digital input from the successive comparison control circuit 62.

A first scaling capacitor 530 has a capacitance value [1C] and is between the first LSB circuit 52 and the first MSB circuit 54 and connected in series between the first LSB circuit 52 and the first MSB circuit 54. More specifically, one end of the first scaling capacitor 530 is connected to an output line 522 of the first LSB circuit 52, and the other end of the first scaling capacitor 530 is connected to an output line 550 of the first MSB circuit 54. The output line 550 outputs the output voltage V_{DAC+} of the positive side to the comparator 60.

The first current source 30a is configured to transmit a current signal to the output line 550 of the first MSB circuit 54 through the first scaling capacitor 530. More specifically, the first current source 30a is connected to one end of the first scaling capacitor 530.

The first current source 30a outputs a current signal to the output line 550 of the first MSB circuit 54 through the first scaling capacitor 530 in synchronization with an input of a digital input to the DAC 50 by the successive comparison control circuit 62. Accordingly, a transient response signal generated in the output line 550 due to a switching operation in the DAC 50 can be eliminated via the current signal of the first current source 30a.

In addition to supplying, by a selector 560 connected to a resistor, the analog input signal V_{IN-} of the negative side in substitution for the analog input signal V_{IN+} of the positive side to the resistor, the second LSB circuit 56 has a substantially same configuration as the first LSB circuit 52. Moreover, in addition to supplying, by a selector 580 connected to a capacitor, the analog input signal V_{IN-} of the negative side in substitution for the analog input signal V_{IN+} of the positive side to the corresponding capacitor, the second MSB circuit 58 has a substantially same configuration as the first MSB circuit 54.

A second scaling capacitor 570 has a capacitance value [1C] and is between the second LSB circuit 56 and the second MSB circuit 58 and connected in series between the second LSB circuit 56 and the second MSB circuit 58. More specifically, one end of the second scaling capacitor 570 is connected to an output line 562 of the second LSB circuit 56, and the other end of the second scaling capacitor 570 is connected to an output line 590 of the second MSB circuit 58. The output line 590 outputs the output voltage V_{DAC-} of the negative side to the comparator 60.

The second current source 30b is configured to transmit a current signal to the output line 590 of the second MSB circuit 58 through the second scaling capacitor 570. More specifically, the second current source 30b is connected to one end of the second scaling capacitor 570.

The second current source 30b outputs a current signal to the output line 590 of the second MSB circuit 58 through the second scaling capacitor 570 in synchronization with an input of the digital input Scrip to the DAC 50 by the successive comparison control circuit 62. Accordingly, a transient response signal generated in the output line 590 due to a switching operation in the DAC 50 can be eliminated via the current signal of the second current source 30b.

### Supplement

Although specific terms are used to describe the embodiments of the present disclosure, it is to be noted that the description provides examples for better understanding and is not to be construed as limitations to the present disclosure or the scope of the appended claims. The scope of the present disclosure is defined in accordance with the scope of the appended claims. Not only the embodiments above but also implementations, embodiments and variation examples not described herein are encompassed within the scope of the present disclosure.

### Notes

An aspect of the techniques disclosed by the present application can be understood with reference to the following.

### (Item 1)

A successive comparison type A/D converter, comprising:
a D/A converter, configured to generate an analog output voltage according to a digital input;
a comparator, configured to compare a voltage according to an analog input signal with an output voltage of the D/A converter; and
a control circuit, configured to input the digital input to the D/A converter, wherein the D/A converter includes: a capacitive D/A conversion circuit, including an output line connected to the comparator and a plurality of capacitors respectively connected to the output line; an isolation capacitor, connected to the output line; and a current source, wherein the current source is configured to output a current signal to the output line through the isolation capacitor in synchronization with an input of the digital input to the D/A converter by the control circuit.

### (Item 2)

The successive comparison type A/D converter according to item 1, wherein the isolation capacitor is a scaling capacitor of the capacitive D/A conversion circuit.

### (Item 3)

The successive comparison type A/D converter according to item 1 or 2, wherein
the successive comparison type A/D converter is configured to convert the analog input signal into an (M+N)-bit digital output signal, in which M and N are positive integers,
the D/A converter further includes a resistive D/A conversion circuit connected to the capacitive D/A conversion circuit via the isolation capacitor,
the resistive D/A conversion circuit is configured to output a signal corresponding to lower M bits to the output line, and
the capacitive D/A conversion circuit is configured to output a signal corresponding to upper N bits to the output line.

### (Item 4)

The successive comparison type A/D converter according to item 1 or 2, wherein
the successive comparison type A/D converter is configured to convert the analog input signal into an (M+N)-bit digital output signal, in which M and N are positive integers,
the D/A converter, when the capacitive D/A conversion circuit is a first capacitive D/A conversion circuit, further includes a second capacitive D/A conversion circuit connected to the first capacitive D/A conversion circuit via the isolation capacitor,
the first capacitive D/A conversion circuit is configured to output a signal corresponding to upper M bits to the output line, and
the second capacitive D/A conversion circuit is configured to output a signal corresponding to the lower N bits to the output line.

### (Item 5)

The successive comparison type A/D converter according to any one of items 1 to 4, wherein the current source is configured to adjust a waveform of the current signal.

### (Item 6)

The successive comparison type A/D converter according to item 5, wherein
the current source includes a source circuit configured to discharge current and a sink circuit configured to draw current,
the source circuit includes a first transistor including a P-channel metal oxide semiconductor field effect transistor (MOSFET), and a plurality of second transistors including P-channel MOSFETs;
the sink circuit includes a third transistor including an N-channel MOSFET, and a plurality of fourth transistors including N-channel MOSFETs;
each of the plurality of second transistors forms a current mirror circuit with the first transistor, and
each of the plurality of fourth transistors forms a current minor circuit with the third transistor.

### (Item 7)

The successive comparison type A/D converter according to item 5 or 6, wherein the digital input includes a control signal for controlling a voltage supplied to each of the plurality of capacitors, and the current source is configured to output the current signal having a waveform corresponding to the control signal.

1. A successive comparison type A/D converter, comprising:
a D/A converter, configured to generate an analog output voltage according to a digital input;
a comparator, configured to compare a voltage according to an analog input signal with an output voltage of the D/A converter; and
a control circuit, configured to input the digital input to the D/A converter, wherein the D/A converter includes:
a capacitive D/A conversion circuit, including an output line connected to the comparator and a plurality of capacitors respectively connected to the output line;
an isolation capacitor, connected to the output line; and
a current source,
wherein the current source is configured to output a current signal to the output line through the isolation capacitor in synchronization with an input of the digital input to the D/A converter by the control circuit.

2. The successive comparison type A/D converter of claim 1, wherein the isolation capacitor is a scaling capacitor of the capacitive D/A conversion circuit.

3. The successive comparison type A/D converter of claim 2, wherein
the successive comparison type A/D converter is configured to convert the analog input signal into an (M+N)-bit digital output signal, in which M and N are positive integers,
the D/A converter further includes a resistive D/A conversion circuit connected to the capacitive D/A conversion circuit via the isolation capacitor,
the resistive D/A conversion circuit is configured to output a signal corresponding to lower M bits to the output line, and
the capacitive D/A conversion circuit is configured to output a signal corresponding to upper N bits to the output line.

4. The successive comparison type A/D converter of claim 2, wherein
the successive comparison type A/D converter is configured to convert the analog input signal into an (M+N)-bit digital output signal, in which M and N are positive integers,
the D/A converter, when the capacitive D/A conversion circuit is a first capacitive D/A conversion circuit, further includes a second capacitive D/A conversion circuit connected to the first capacitive D/A conversion circuit via the isolation capacitor,
the first capacitive D/A conversion circuit is configured to output a signal corresponding to upper M bits to the output line, and
the second capacitive D/A conversion circuit is configured to output a signal corresponding to the lower N bits to the output line.

5. The successive comparison type A/D converter of claim 1, wherein the current source is configured to adjust a waveform of the current signal.

6. The successive comparison type A/D converter of claim 5, wherein
the current source includes a source circuit configured to discharge current and a sink circuit configured to draw current,
the source circuit includes:
a first transistor including a P-channel metal oxide semiconductor field effect transistor (MOSFET); and
a plurality of second transistors including P-channel MOSFETs,
the sink circuit includes:
a third transistor including an N-channel MOSFET; and
a plurality of fourth transistors including N-channel MOSFETs,
each of the plurality of second transistors forms a current mirror circuit with the first transistor, and
each of the plurality of fourth transistors forms a current mirror circuit with the third transistor.

7. The successive comparison type A/D converter of claim 5, wherein
the digital input includes a control signal for controlling a voltage supplied to each of the plurality of capacitors, and
the current source is configured to output the current signal having a waveform corresponding to the control signal.
